(19) United States
(12) Patent Application Publication
(10) Pub. No.: US 2009/0316374 A1
(43) Pub. Date: Dec. 24, 2009

(54) Reduced Porosity High-K Thin Film Mixed Grains for Thin Film Capacitor Applications

(75) Inventor: Cengiz A. Palanduz, Chandler, AZ (US)

Correspondence Address: BLAKELY SOKOLOFF TAYLOR & ZAFMAN LLP, 1279 OAKMEAD PARKWAY, SUNNYVALE, CA, 94085-4040, US

(73) Assignee: INTEL CORPORATION, Santa Clara, CA (US)

(21) Appl. No.: 12/549,325

(22) Filed: Aug. 27, 2009

Related U.S. Application Data
(62) Division of application No. 11/096,685, filed on Mar. 31, 2005.

(51) Int. Cl. H05K 1/16; H01G 4/06

(52) U.S. Cl. 361/765; 361/321.1

(57) ABSTRACT

A method including forming a layer of a first ceramic material on a substrate; and after forming the layer, forming a second ceramic material on the layer of the first ceramic material, the formed second ceramic material including an average grain size less than a grain size of the first ceramic material. An apparatus including a first electrode; a second electrode; and a sintered ceramic material, wherein the ceramic material comprises first ceramic grains defining grain boundaries therebetween and second ceramic grains having an average grain size smaller than a grain size of the first ceramic grains. A system including a device including a microprocessor, the microprocessor coupled to a circuit board through a substrate, the substrate including a capacitor structure formed on a surface, the capacitor structure including a first electrode, a second electrode, and a sintered ceramic material disposed between the first electrode and the second electrode.

### CROSS-REFERENCE TO RELATED APPLICATION

The application is a divisional of co-pending U.S. patent application Ser. No. 11/096,685, filed Mar. 31, 2005.

### FIELD

Circuit structures and passive devices.

### BACKGROUND

It is desirable to provide decoupling capacitance in a close proximity to an integrated circuit chip or die. The need for such capacitance increases as the switching speed and current requirements of chips or dies becomes higher. Thus, the need for a high number of passive components for high density integrated circuit chips or dies, the resultant increasing circuit density of printed wiring boards (PWB), and a trend to higher frequencies in the multi-gigaHertz range are among the factors combining to increase pressure on passive components surface-mounted on package substrates or PWBs. By incorporating embedded passive components (e.g., capacitors, resistors, inductors) into the package substrate or PWB, improved performance, better reliability, smaller footprint, and lower cost can be achieved.

Capacitors are the predominant passive component in most circuit designs. Typical materials for suitable embedded capacitor components, such as polymer and high-dielectric constant (high-k) ceramic powder composites or high-k ceramic powder and glass powder mixtures, are generally limited to a capacitance density on the order of nanoFarad/cm² and 0.1 microFarad/cm².

Creating thin films having a relatively large capacitance density, that is, a capacitance density above about one microFarad/cm², on metal sheets that may serve as conductor material presents a number of challenges. One way to achieve large capacitance density would be to achieve a large dielectric constant, given that capacitance density and dielectric constant are directly proportional to one another. It is known that the dielectric constant of a material is, among other things, a function of the grain size of that material. In particular, as the grain size of a material increases, generally, so will its dielectric constant. However, growing thin films having large grain sizes, that is, thin films having grain sizes above about 50 nanometers (nm) to about 100 nm is a challenge. For example, growing a large grain microstructure requires an optimum combination of nucleation and grain growth. This is hard to achieve on a polycrystalline metal sheet. Typically, the multitude of random sites on a polycrystalline metal sheet act as nucleation sites, resulting in a microstructure with very small grain size (about 10 nm to about 50 nm). Once the film microstructure is composed of a large number of small grains, further heating will generally not result in a large grain microstructure, because a large number of similar-sized grains cannot grow into each other to form larger grains.

Attempts at creating thin films having a large capacitance density have shifted toward reducing a thickness of the deposited thin film dielectric, while avoiding the problems noted above with respect to creating dielectrics of large grain size. Thus, the prior art typically focuses on relatively small grain sized thin film technology (that is dielectric thin films having grain sizes in the range from about 10 nm to about 50 nm, with dielectric constants ranging from about 100 to about 450). To the extent that the capacitance density of a material is known to be inversely proportional to its thickness, the prior art has aimed at keeping the thickness of such dielectric films on the order of about 0.1 microns. However, disadvantageously, such films have tended to present serious shorting issues. First, a surface roughness of the metal sheet onto which the dielectric film has been deposited, to the extent that it is usually significant with respect to a thickness of the dielectric film, tends to present peaks and valleys into the dielectric film which in turn can lead to a direct shorting between the electrodes of a capacitor that includes the dielectric film. In addition, again, since a thickness of the dielectric film is small, voids typically present in the film will allow metal from at least one of the capacitor electrodes to seep into the voids, leading to shorting and leakage between the electrodes.

Voids in dielectric layers are disadvantageous for a number of other reasons. First, because of the presence of air pockets brought about as a result of the presence of voids, stress concentration points are typically created in the dielectric film, thus increasing the risk of crack propagation therein. In addition, to the extent that the dielectric constant of air is very small, the presence of air pockets results in a decrease in the overall dielectric constant of the dielectric layer. Thus, voids present disadvantages with respect to both the mechanical integrity and the electrical performance of a dielectric layer. The prior art proposes solving the problem of voids by exposing the dielectric layer to relatively long periods of sintering in order to densify the layer. However, such a solution disadvantageously increases the thermal budget required for the fabrication of a dielectric film, increasing cost while not necessarily guaranteeing a satisfactory reduction in the number of voids.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a cross-sectional schematic side view of an embodiment of a chip or die package suitable for mounting on a printed circuit or wiring board.

FIG. 2 shows a cross-sectional schematic side view of the package substrate of FIG. 1.

FIG. 3 describes a process flow for forming a dielectric film for a capacitor structure.

FIG. 4 shows a schematic side view of a first conductor sheet having a layer of dielectric material including large grains.

FIG. 5 shows a schematic side view of the structure of FIG. 4 following the formation of a layer of dielectric material including small grains on a surface of the layer of dielectric material including large grains.

FIG. 6 shows a schematic side view of the structure of FIG. 5 following the formation of a second conductor sheet on the dielectric material.

### DETAILED DESCRIPTION

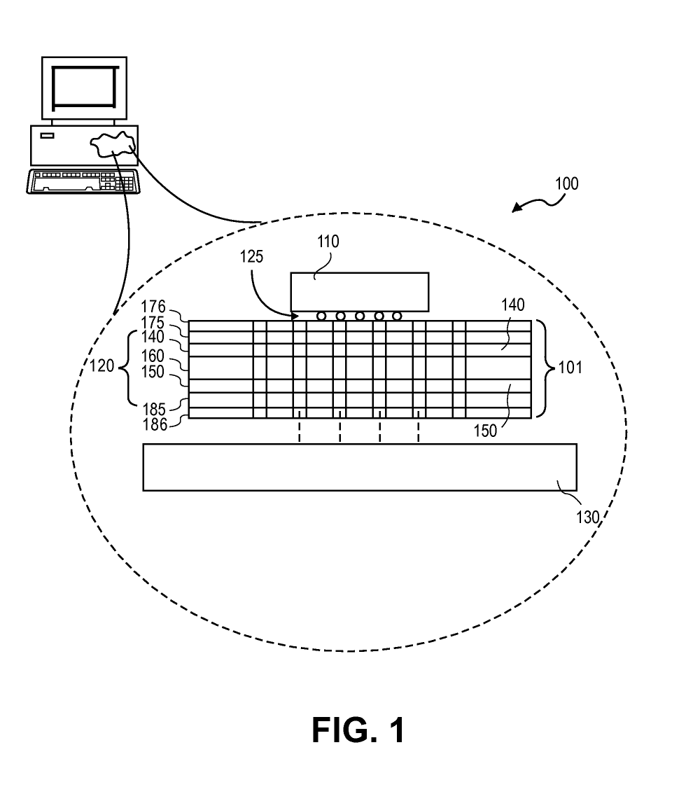

FIG. 1 shows a cross-sectional side view of an integrated circuit package that can be physically and electrically connected to a printed wiring board or printed circuit board (PCB) to form an electronic assembly. The electronic assembly can be part of an electronic system such as a computer (e.g., desktop, laptop, hand-held, server, etc.), wireless communication device (e.g., cellular phone, cordless phone, pager, etc.), computer-related peripheral (e.g., printers, scanner, monitors, etc.), entertainment device (e.g., television, radio, stereo, tape and compact disc player, videocassette recorder, MP3 (Motion Picture Experts Group, Audio Layer 3) player, etc.), and the like. FIG. 1 illustrates the package as part of a desktop computer.

FIG. 1 shows electronic assembly 100 including die 110 physically and electrically connected to package substrate 101. Die 110 is an integrated circuit die, such as a processor die. Electrical contact points (e.g., contact pads on a surface of die 110) are connected to package substrate 101 through conductive bump layer 125. Package substrate 101 may be used to connect electronic assembly 100 to printed circuit board 130, such as a motherboard or other circuit board.

In one embodiment, package substrate 101 includes one or more capacitor structures. Referring to FIG. 1, package substrate 101 includes capacitor structure 140 and capacitor structure 150 embedded therein. Capacitor structure 140 and capacitor structure 150 are connected to opposite sides of core substrate 160. In another embodiment, capacitor structure 140 and capacitor structure 150 may be stacked one on top of the other.

In one embodiment, core substrate 160 is an organic core such as an epoxy including a fiberglass reinforced material, also called pre-preg. This configuration may be referred to as an integrated thin film capacitor (iTFC) system, where the capacitor(s) is(are) integrated into the package substrate rather than, for example, an interposer between the die and the package substrate. Overlying capacitor structure 140 is adhesion layer 175 (e.g., silica-filled epoxy). Underlying capacitor structure 150 is adhesion layer 185. Overlying adhesion layer 175 is build-up layer 176. Underlying adhesion layer 185 is build-up layer 186. Adhesion layer 175 and adhesion layer 185 act as adhesion layers to the overlying and underlying build-up layers 176 and 186, respectively. Each build-up layer includes traces (e.g., copper traces) for lateral translation of contact points between die 110 and package substrate 101, and package substrate 101 and printed circuit board 130, respectively, and typically solder resist as a top layer. The region made up of the combination of layers, 185, 150, 160, 140 and 175, is referred to herein as functional core 120.

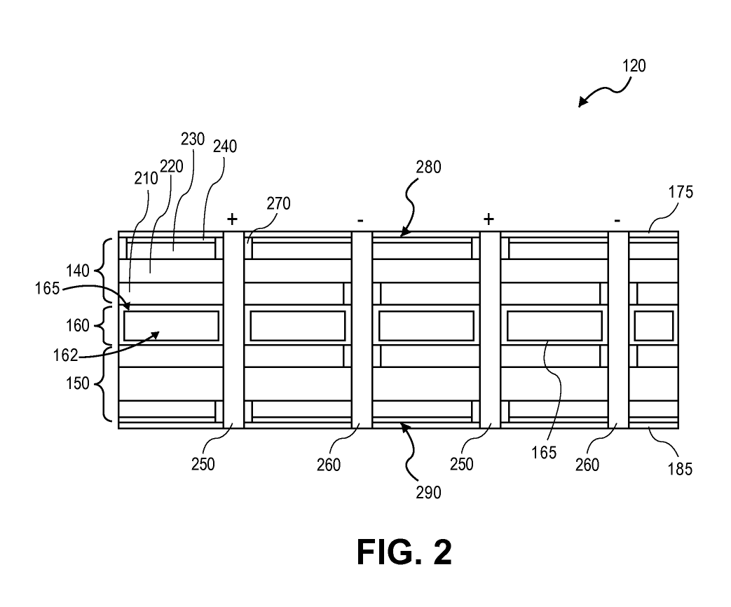

FIG. 2 shows a magnified view of a portion of functional core 120. Functional core 120 includes core substrate 160 and having a thickness, in one embodiment, on the order of 200 microns (μm) to 700 μm. In another embodiment, core substrate 160 has a thickness on the order of 200 μm to 300 μm. In one embodiment, core substrate 160 includes core 162, such as a glass-fiber reinforced epoxy, and shell 165, such as a silica-particle filled epoxy.

Capacitor structure 140 is connected to one side of core substrate 160 (a top side as viewed). Capacitor structure 140 includes first conductor 210 proximal to core substrate 160 and second conductor 230. Disposed between first conductor 210 and second conductor 230 is dielectric material 220. Capacitor structure 150 is connected to an opposite side of core substrate 160 (a bottom side as viewed) and has a similar configuration of a dielectric material disposed between two conductors. Overlying capacitor structure 140 and capacitor structure 150 of functional core 120 (on sides opposite sides facing core substrate 160) is adhesion layer 175 and adhesion layer 185, respectively, made of, for example, an organic material and having a representative thickness on the order of 10 microns (μm) to 50 μm. Build-up layer 176 and build-up layer 186 of FIG. 1 would be deposited on these adhesion layers. As noted above, the build-up layers may include traces and contact points to connect package substrate to a chip or die and to a printed circuit board, respectively, and solder resist as a top layer.

In one embodiment, first conductor 210 and second conductor 230 of capacitor structure 140 are electrically conductive material. Suitable materials include, but are not limited to, a nickel or a copper material. In one embodiment, dielectric material 220 is a ceramic material having a relatively high dielectric constant (high-k). Suitable materials for dielectric material 220 include, but are not limited to, barium titanate (BaTiO₃), barium strontium titanate ((Ba, Sr) TiO₃), and strontium titanate (SrTiO₃).

In one embodiment, capacitor structure 140 includes first conductor 210 and second conductor 220 having a thickness on the order of 20 μm to 50 μm, and dielectric material 220 of a high-k ceramic material of a thickness on the order of 1 μm to 3 μm and, in another embodiment, less than 1 μm. Capacitor structure 150, in one embodiment, is similar to capacitor structure 140.

In the embodiment of functional core 120 shown in FIG. 2, capacitor structure 140 includes overlayer 240 on second conductor 230. Overlayer 240 is an optional electrically conductive layer that may be used in an instance where second conductor 230 is a material that may not be compatible or may be less compatible with materials or processing operations to which functional core 120 may be exposed. For example, in one embodiment, second conductor 230 is a nickel material. To render functional core 120 transparent to subsequent processing operations or compatible with materials to which functional core 120 may be exposed, overlayer 240 is a copper material. Representatively, overlayer 240, if present, may have a thickness on the order of a few microns.

FIG. 2 shows a number of conductive vias extending through functional core 120 between surface 280 and surface 290. Representatively, conductive via 250 and conductive via 260 are electrically conductive materials (e.g., copper or silver) of suitable polarity to be connected to power or ground contact points of die 110 (e.g., through conductive bump layer 125 to contact pads on die 110 of FIG. 1). In this manner, conductive via 250 and conductive via 260 extend through capacitor structure 140, core substrate 160, and capacitor structure 150. Conductive vias 250 and 260 may be insulated, where desired, from portions of capacitor structure 140 or capacitor structure 150 by sleeves 270 of a dielectric material.

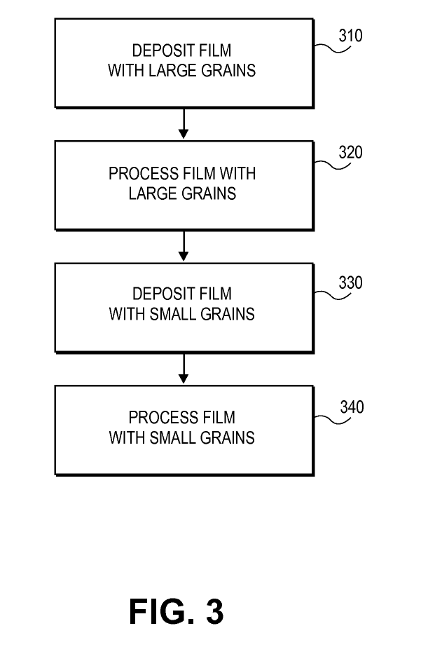

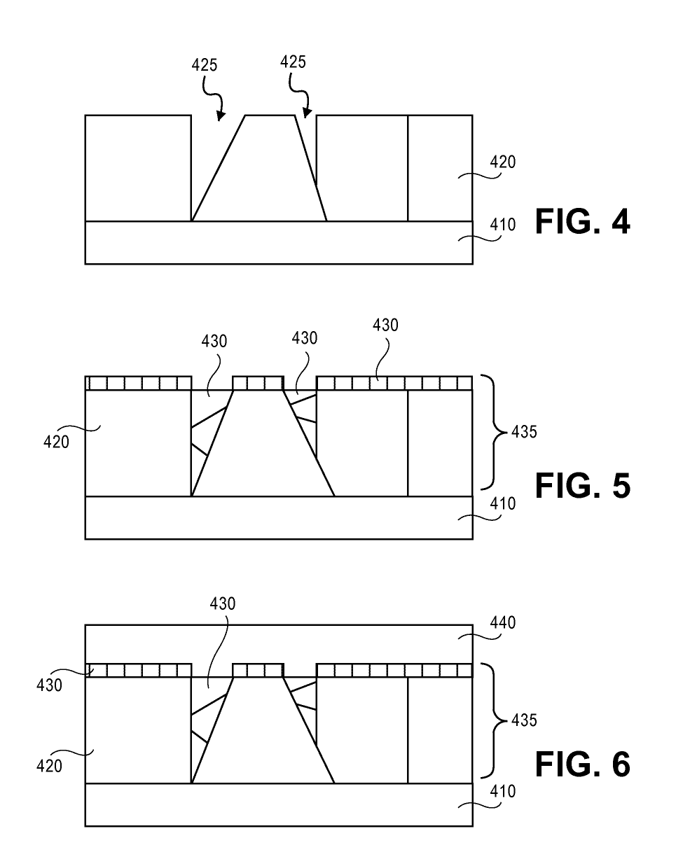

FIG. 3 presents a process for forming a capacitor structure such as capacitor structure 140 and capacitor structure 150. Specifically, FIG. 3 presents a process for forming a dielectric material of a capacitor structure (e.g., dielectric material 220 of capacitor structure 140). A capacitor structure, such as capacitor structure 140 and/or capacitor structure 150 may be formed and then separately connected to core substrate 160. FIGS. 4-6 show formation processes in connection with portions of the process flow described in FIG. 3, notably an embodiment of forming a capacitor structure.

In one embodiment of forming a capacitor structure of a package structure, a sheet (e.g., foil) of a first conductor material is provided as an initial substrate. Representatively, a sheet (e.g., foil) of nickel having a desired thickness is provided. Representative thickness are on the order of several microns to tens of microns depending on the particular design parameters. In one embodiment, the nickel sheet would be a standard rolled or plated nickel sheet. The dimensions of a sheet suitable as a first conductor may vary depending, for example, on the requirements of board shops involved in their production. For example, it may be desirable to process a sheet having a length and width dimension on the order of 200 millimeters (mm) to 400 mm from which a number of capacitor structures can be singulated. Individual capacitor could have sizes varying between silicon die dimensions to substrate dimensions.

Directly onto a surface of the first conductor, a ceramic material is deposited as a green sheet dielectric material (block 310). Representatively, ceramic powder particles may be deposited onto a surface, including an entire surface of a first conductor sheet or foil. In one embodiment, it is desired to form a dielectric layer of high-k material having a thickness on the order of one micron or less. Ceramic powder particles having an average grain size on the order of 60 nanometers (nm) to 300 nm are suitable.

In one embodiment, ceramic powder particles having an average grain size on the order of 60 nm to 300 nm are relatively large grain that, when formed into a film, may yield a relatively high dielectric constant (e.g., on the order of 500 to 5,000). One technique for depositing ceramic particles is through a sol gel precursor composition in which the material is deposited in a liquid or pseudo-liquid phase using an organic liquid solution of organic molecules embedded with metal atoms. For a dielectric material of barium titanate, a suitable precursor composition to form the dielectric material may, by way of example, include either: (1) barium acetate dissolved in acetic acid and mixed with titanium tetra-isopropoxide and isopropanol; (2) barium acetate dissolved in acetic acid mixed with titanium tetra n-butoxide stabilized with acetyl acetone and diluted with 2-methoxyethanol; and (3) barium propionate and titanium tetra n-butoxide stabilized with acetyl acetone dissolved with a mixture of propionic acid 1-butanol. To form a dielectric material of barium, strontium titanate, strontium may also be added in any of the examples, for example, as a strontium acetate in Examples (1) and (2) or strontium propionate in Example (3).

In one embodiment, to achieve large grains of dielectric material, the concentration of the metal component (e.g., barium, titanium, strontium) has a molar concentration of 10 percent or greater in the precursor composition.

Deposition of a precursor composition onto a surface of the first conductor may be performed by spin-on, spray, or dipping techniques. In one embodiment, the precursor composition of a dielectric material is deposited to a thickness on the order of 0.3 microns (μm) to one μm. Following deposition, the precursor composition, including the dielectric particles with relatively high dielectric constant, is processed to dry, burn-out organics, and anneal (sinter) the dielectric material (block 320). For drying, the film of the precursor composition may be exposed to temperatures of 100° C. to 200° C. for 15 minutes to 30 minutes. For organic burn-out, the dried film may be exposed to temperatures on the order of 300° C. to 500° C. for about one hour to three hours to yield an intermediate film. For annealing or sintering, the intermediate film is exposed to a relatively high temperature to promote large grain size. A representative temperature is on order of 700° C. or greater, in one embodiment, greater than 700° C. (e.g., 700 to 1000° C.). In one embodiment, the annealing (sintering) is accomplished relatively slowly over a period of, for example, one half hour to three hours. One advantage of relatively larger grains of dielectric material is that higher grains tend to increase a dielectric constant of a material. Large grains also typically are relatively porous, particularly at grain boundaries. The porosity of a thin film of a dielectric in a capacitor may lead to shorting or leakage around, for example, grain boundaries.

Following annealing, in certain embodiments it may be desirable to deposit one or more additional large grain dielectric film layers. The deposition and processing operations described above may be repeated for each such layer.

An alternative to the sol gel deposition and processing described above is to deposit the dielectric material using sputtering techniques. The first conductor material may be heated (e.g., up to 1000° C.) to achieve grain growth during deposition. Alternatively, the dielectric material may be deposited (e.g., and partially annealed) and, once deposited, annealed at high temperature to promote large grain growth.

FIG. 4 shows a structure including first conductor 410 having first dielectric film 420 deposited on a surface thereof (an upper surface as viewed). In this representation, a thickness of first conductor 410 appears less than a thickness of first dielectric film 420. It is appreciated that this may not be the typical situation. In fact, for a capacitor structure according to current designs, a conductor may be much thicker than a dielectric film. Therefore, FIG. 4 and FIG. 5 and FIG. 6 should not be understood to illustrate an indication of relative thickness at least for a capacitor structure.

FIG. 4 shows dielectric film 420 having relatively large grains, e.g., on the order of 60 nm to 300 nm formed according to the process described above with reference to FIG. 3 and block 310 and block 320. FIG. 4 shows dielectric film 420 as a single layer of grains. In another embodiment, dielectric film 420 may have two or more layers. FIG. 4 also illustrates the porosity of dielectric film 420 by showing gaps 425 at grain boundaries. It is appreciated that where a subsequent metal layer (conductor) is formed on dielectric film 420 (opposite first conductor 410) to form a capacitor, the subsequent metal layer and first conductor 410 may be shorted together through, for example, a gap at a grain boundary.

To reduce the porosity of relatively large grain dielectric films, a film including relatively small grains (e.g., 10 nm to 50 nm) may be deposited on dielectric film 420. According to the method of FIG. 3, following the processing of a film with relatively large grains, a film with relatively small grains is deposited (block 330). In one embodiment, a film including small dielectric grains may be deposited using sol gel techniques such as described above. To achieve small grains, the concentration of a metal component of a precursor composition (e.g., a sol gel composition) is formed at a concentration of ten percent (0.1 M) or less. A sol gel precursor composition including small grains may be deposited by spin-on, spray or dipping techniques. In one embodiment, a precursor composition including small grains is deposited to a thickness on the order of 0.01 micrometer. In one embodiment, the thickness of a film including small grains is selected to have a minimal effect on the overall dielectric constant of the overall film. In one embodiment, the film created in block 310 and block 320, has a dielectric constant of 500 and a thickness of 0.5 micrometer, and the film created in block 330 and block 340, would have a dielectric constant of 100 and a thickness of 0.01 micrometer.

Following deposition, the precursor composition including small grains is processed (block 340). Processing includes, in one embodiment, heat treating to dry, burn-out organics, and anneal (sinter) the film. In one embodiment, to achieve a film including relatively small grains, the film is annealed (sintered) at a temperature of 500° C. or less (e.g., 300° C. to 500° C.). Although sol gel deposition and processing is described, other techniques, such as sputtering, may be used to form a film including relatively small grains.

FIG. 5 shows the structure of FIG. 4 following the deposition and processing of dielectric film 430 on dielectric film 420. Dielectric film 430, in one embodiment, has a plurality of relatively small grains (e.g., on the order of 10 nm to 50 nm). The film is deposited on a surface of dielectric film 420 and the small grains tend to fill voids in dielectric film 420, including gaps 425 at grain boundaries. Thus, dielectric film 430 tends to reduce the porosity of composite dielectric film 435 (including dielectric film 420 and dielectric film 430).

FIG. 6 shows the structure of FIG. 5 following the formation of second conductor 440. In one embodiment, second conductor 440 is a nickel material that may be deposited on composite dielectric film 435 as a paste and thermally treated. Alternatively, second conductor 440 of a nickel material may be laminated to composite dielectric film 435. Again, FIG. 5 may not accurately reflect the thickness of second conductor 440 relative to the composite dielectric film.

For completeness, various subsequent processing operations are described to form a package substrate (e.g., package substrate 101 in FIG. 1) utilizing a capacitor structure or structures formed according to the method of FIG. 3 and illustrated in FIGS. 4-6. As noted above, in one embodiment, first conductor 410 and second conductor 440 are a nickel material. Copper coating may be desirable to make the capacitor structure transparent to subsequent processing operations to which the capacitor structure or the package substrate may be exposed. In the example where first conductor 410 and second conductor 440 are a nickel material, for example, it may be desirable to coat an exposed surface of the first or second conductor with a copper material.

The capacitor structure may be attached to a core substrate, such as an organic core substrate as discussed above. In the example where a copper layer overlays a conductor, the copper surface may need to be roughened (e.g., by etching) in order to enhance lamination. Even in the case where both top and bottom electrodes are nickel, the outer nickel surface can be roughened by, for example, etching. The capacitor structure may be attached to one surface of the base substrate. A separate capacitor structure formed in a similar manner could be laminated to another surface, such as shown above in FIG. 2 and described in the accompanying text.

Following laminating of one or more capacitor structures to a core substrate, the package substrate may be patterned. Conventional patterning operations, such as mechanical drilling, drilling via holes in epoxy with laser, lithography and copper plating operations used in via formation may be employed. The capacitor structure may also be patterned to form individual capacitors. A complete organic substrate may be formed by adding build-up layers of an organic material (e.g., epoxy or glass particle-filled epoxy) onto the substrate.

The above description is related to forming capacitor structures within package substrates. Similar techniques may be used in the formation of capacitors in other environments, such as in printed wiring boards (e.g., printed circuit boards).

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. An apparatus comprising:
a first electrode;
a second electrode; and
a sintered ceramic material disposed between the first electrode and the second electrode,
wherein the ceramic material comprises first ceramic grains defining grain boundaries there between and second ceramic grains having an average grain size smaller than a grain size of the first ceramic grains disposed in the grain boundaries.

2. The apparatus of claim 1, wherein at least one of the first electrode and the second electrode comprises a copper material.

3. The apparatus of claim 1, wherein the average grain size of the second ceramic grains is on the order of 10 nanometers to 50 nanometers.

4. The apparatus of claim 3, wherein an average grain size of the first ceramic grains is at least 60 nanometers.

5. The apparatus of claim 1, wherein the ceramic material has a thickness on the order of one micron or less.

6. A system comprising:
a computing device comprising a microprocessor, the microprocessor coupled to a printed circuit board through a substrate, the substrate comprising a capacitor structure formed on a surface, the capacitor structure comprising:
a first electrode,
a second electrode, and
a sintered ceramic material disposed between the first electrode and the second electrode,
wherein the ceramic material comprises first ceramic grains defining grain boundaries there between and second ceramic grains having an average grain size smaller than a grain size of the first ceramic grains disposed in the grain boundaries.

7. The system of claim 6, wherein at least one of the first electrode and the second electrode comprises a copper material.

8. The system of claim 6, wherein the average grain size of the second ceramic grains is on the order of 10 nanometers to 50 nanometers.

9. The system of claim 8, wherein an average grain size of the first ceramic grains is at least 60 nanometers.

10. The system of claim 6, wherein the ceramic material has a thickness on the order of one micron or less.
